(19) United States
(12) Patent Application Publication
(10) Pub. No.: US 2008/0012189 A1
(43) Pub. Date: Jan. 17, 2008

(54) SYSTEM FOR STRUCTURING SOLAR MODULES

(76) Inventor: Dieter Manz, Schlaitdorf (DE)

Correspondence Address: Striekr, Striker & Stenby, 103 East Neck Road, Huntington, NY, 11743, US

(21) Appl. No.: 11/778,199

(22) Filed: Jul. 16, 2007

(30) Foreign Application Priority Data
Jul. 17, 2006 (DE) 10 2006 033 296.2

(51) Int. Cl. B25B 11/00

(52) U.S. Cl. 269/21

(57) ABSTRACT

A system for structuring solar modules includes a transportation system for transporting a solar module in one transport plane in a first axial direction and a first transverse axis with a structuring tool, wherein the transportation system is configured as an air cushion system.

### CROSS-REFERENCE TO A RELATED APPLICATION

The invention described and claimed hereinbelow is also described in German Patent Application DE 10 2006 033 296.2 filed on Jul. 17, 2006. This German Patent Application, whose subject matter is incorporated here by reference, provides the basis for a claim of priority of invention under 35 U.S.C. 119(a)-(d).

### BACKGROUND OF THE INVENTION

The invention relates to a system for structuring solar modules, comprising a transportation system which transports a solar module in one transport plane in a first axial direction and a first transverse axis with a structuring tool.

Glass substrates are used to produce thin film solar modules which are usually coated with three layers in coating plants. For series connection of the individual cells inside a solar module, the layers are selectively separated in three structuring steps whereby lines are incorporated into the solar module.

There is a requirement to be able to carry out this structuring for solar modules with different layer structures on a single system.

### SUMMARY OF THE INVENTION

It is therefore the object of the present invention to provide a system whereby this requirement can be satisfied.

According to the invention, this object is achieved by a system for structuring solar modules, comprising a transportation system for transporting a solar module in one transport plane in a first axial direction and a first transverse axis with a structuring tool, wherein the transportation system comprises an air cushion system.

With such a system it is possible to separate and decouple the tool axis (transverse axis) and the transport axis of the solar module. By using the air cushion system, non-contact transportation and non-contact support of the solar module can be achieved at least at a location where processing takes place. This ensures gentle and reliable transportation of the solar module substrate.

In a particular preferred embodiment, it can be provided that the air cushion system is interrupted by a gap in a processing region, in particular in the region of the first transverse axis. Laser beams, for example, which can be used for structuring one or a plurality of layers can be coupled into the substrate through this gap. Furthermore, such a gap can be used for coupling in transmitted light for calibrating the substrate and for carrying out quality assurance steps by means of image processing.

It is particularly preferable if a pressure-vacuum table for simultaneously generating a vacuum and an excess pressure between the solar module is provided in at least one processing area. As a result, pressure and vacuum act simultaneously on the solar module. As a result, the distance of the solar module from the plate and thus also from the structuring tools can be kept precisely in the range of a few micrometers.

One embodiment is characterised in that at least parts of a laser system which can be moved transversely to the first axial direction are arranged on the first transverse axis as a structuring tool. It is thereby possible to perform at least one structuring step using a laser, wherein the laser can be coupled-in at the back through the glass substrate of the solar module. The transverse axis arranged transversely to the first axial direction (direction of transport of the solar module) makes it possible to achieve structuring parallel to the short and also to the long side of the solar module.

In a particularly preferred embodiment, it can be provided that parts of a plurality of laser systems are arranged on the first transverse axis. It is thereby possible to apply a plurality of laser beams adjacent to one another transversely to the direction of processing so that a plurality of tracks can be processed in parallel. Depending on the layer structure of the solar module, in particular if cells of amorphous silicon are used, all layers of the solar module can be structured from the back of the solar module by means of a laser.

A laser system in the sense of the invention can be a laser itself or a laser together with laser optics. In this case, it can be provided that one or a plurality of lasers or one or a plurality of laser optics are provided on the first transverse axis for guiding laser beams. If the laser is arranged directly on the transverse axis, this can be moved along the transverse axis. However, it is also feasible to arrange one or a plurality of lasers in a fixed position and only move the laser optics, or if a plurality of laser beams are to be aligned simultaneously onto the solar module, a plurality of laser optics, along the transverse axis. Alternatively, a structuring tool for mechanical structuring can be provided on the first transverse axis.

In a particularly preferred embodiment, a second transverse axis can be provided. Further processing or analytical steps can thus be carried out with the same system.

According to a further development, one or a plurality of structuring tools, in particular for mechanical structuring and/or edge deletion can be arranged on the second transverse axis. The range of use of the system is thereby expanded. For example, one layer can be processed by means of a laser and the other two layers can be processed by means of mechanical structuring tools, for example, styli. Naturally it is also feasible to provide mechanical structuring tools on the first transverse axis. A plurality of structuring tools can be provided on both transverse axes transversely to the axial direction of the respective axis.

Particular advantages are obtained if one transverse axis is arranged above and one transverse axis is arranged below the transport plane. Thus, the solar module can be processed on both sides. The equipping and arrangement of the transverse axes can be suitably selected depending on the orientation in which the solar module is to be supplied, with the glass substrate at the bottom or at the top. For example, the first transverse axis can have a laser system which is located below the transport plane, where the glass substrate points towards the laser system. A mechanical structuring tool can be provided on a transverse axis arranged above the transport plane for structuring at least some upwardly pointing layers. If solar modules having upwardly directed glass substrates are to be supplied, it is advantageous to arrange the laser system above the transport plane and a mechanical structuring tool below the transport plane.

In one embodiment, a calibration system for calibrating the lines to be structured can advantageously be arranged on the first or second transverse axis. For example, a camera system can be provided as a calibration system for calibrating the lines and for quality testing. In this case, the camera can be arranged on a transverse axis located above the transport plane together with an illumination unit. The camera can be used to determine the line profile of the previously implemented structuring or incorporated reference marks. For example, measurement points are recorded every 10-20 cm for calibrating the structuring line of the second layer. The recorded line profile is the basis for the subsequent structuring of the second layer. For this purpose a curve is interpolated using the measured support points.

For the structuring of the layers, the calibration can alternatively be made by measuring the reference marks which have been incorporated, for example, in a preceding step.

The camera can also be used to assess the quality of the lines produced. Criteria, in addition to the track width, are the position of the track and the quality (grooves).

Particles are formed during the structuring. It is therefore advantageous if the first or the second transverse axis has a suction device. In particular, it can thereby be achieved that particles formed are completely removed so that the subsequent operating mode of the solar module is not impaired.

For exact positioning of the structuring tools, it is advantageous if a distance measuring system is provided on the first and/or the second transverse axis. It can thereby be ensured that the structuring is carried out with a high precision. Preferably high-precision linear measuring systems are used as distance measuring systems, where direct distance measurements are made using rules.

Further advantages are obtained if linear motors are provided on the first and/or second transverse axis for driving the structuring tools or the calibration system. By using linear motors, good dynamics, precision and speed are achieved. Linear drives are maintenance-free.

In one embodiment, retaining means for fixing the solar module can be provided on at least one edge region, preferably at least two opposing edge regions, of the solar module. In particular, the solar modules can be fixed on both longitudinal sides by retaining strips.

Exact positioning of the solar module in the transport direction can be achieved if the retaining means can be driven by linear motors in the first axial direction.

Further advantages are obtained if the transport system has aligning means for aligning the solar module. This is particularly advantageous if the solar module is placed on an air cushion. The solar module can be aligned in the transverse and longitudinal direction by mechanical centring. As soon as the solar module has occupied the correct position, it can be fixed on both longitudinal sides by the retaining means.

Further features and advantages of the invention are obtained from the following description of exemplary embodiments of the invention with reference to the figures in the drawings which show details important to the invention, and from the claims. The individual features can each be implemented individually by themselves or as a plurality in any combination in one variant of the invention.

The novel features which are considered as characteristic for the present invention are set forth in particular in the appended claims. The invention itself, however, both as to its construction and its method of operation, together with additional objects and advantages thereof, will be best understood from the following description of specific embodiments when read in connection with the accompanying drawings.

### BRIEF DESCRIPTION OF THE DRAWINGS

FIG. 1 is a perspective view of a system according to the invention; and

FIG. 2 is a plan view of the system according to the invention.

### DESCRIPTION OF THE PREFERRED EMBODIMENTS

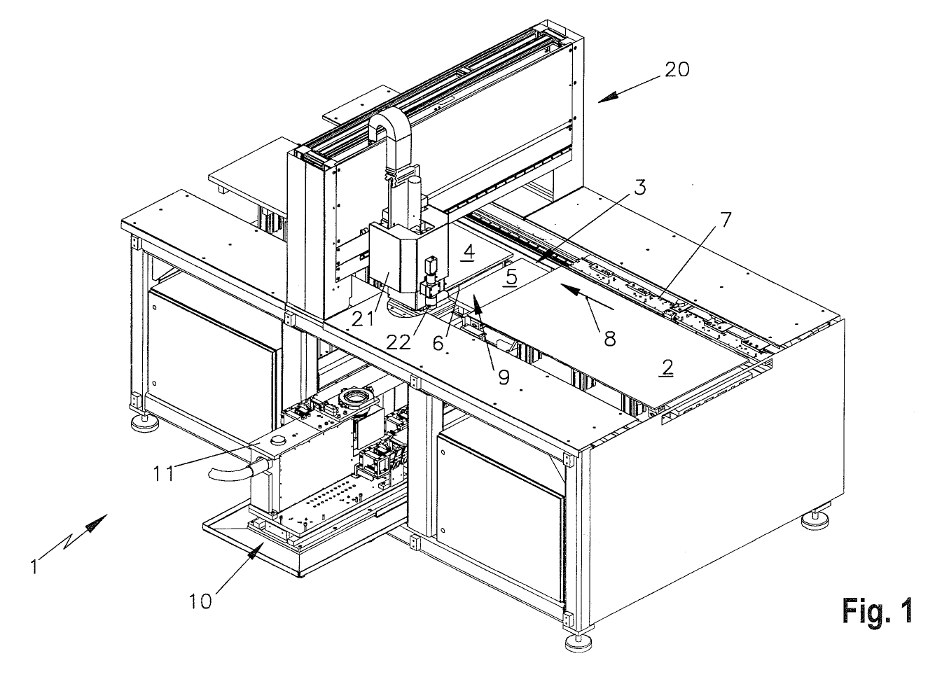

FIG. 1 shows a system 1 for structuring solar modules 2. The solar module 2 is transferred to a transportation system 3 via an interface not shown for loading and unloading solar modules 2. The transportation system 3 comprises an air cushion system which, in the exemplary embodiment, comprises two plates 4, 5 separated by a gap 6.

Openings are provided in the plates 4, 5, at least in the area of the gap 6 through which the underside of the solar module 2 can be exposed to excess pressure and also to a vacuum. The area of the gap 6 can thus be configured as a pressure-vacuum table. An air cushion can thus be produced which keeps the solar module 2 at a constant distance from the plates 4, 5. The solar module 2 is held at least on one longitudinal side by means of a retaining means 7 configured as a retaining strip. The retaining means 7 can be driven in the direction of the first axial direction 8 by means of linear drives not shown. The solar module 2 can thus be displaced into the processing region 9 and moved relative to structuring tools to be described in greater detail.

In the exemplary embodiment, a first transverse axis 10 is located underneath the transport plane of the solar module 2. The transverse axis 10 has a laser system 11 as a structuring tool. A laser beam can be coupled into the substrate of the solar module 2 through the gap 6. One or a plurality of layers applied to the top of the substrate of the solar module 2 can thus be structured. The laser system 11 can be moved by a linear drive not shown, transversely to the axial direction 8. As a result of the relative movement of the laser system 11 and the solar module 2, the solar module 2 can be structured both in the axial direction 8, that is parallel to its longitudinal side and also transversely to the axial direction 8, that is parallel to a short side.

The system 1 also has a second transverse axis 20 which combines a suction device, a camera system and a mechanical structuring tool 22 in one unit 21. The suction device, the camera system and the mechanical tool 22 need not necessarily be combined to form one unit but can also be arranged separately from one another on the second transverse axis 20. It is also not necessary for all three devices to be continuously present. For example, it is feasible to merely provide the camera system.

The unit 21 can be moved transversely to the axial direction 8 by means of linear drives. For example, the mechanical tool 22 can configured as a stylus so that layers of the solar module 2 can be structured mechanically. Particles accumulated during the structuring are removed by the suction device. It is feasible that a plurality of mechanical tools 22 are arranged adjacently to one another in the axial direction 8 on the unit 21. The camera system can be used for calibrating lines.

Not shown are protective devices for protecting users from laser radiation. The laser system 11 and the unit 21 can be coupled to the transverse axes 10, 20 and thus are also exchangeable. It is furthermore feasible that the mechanical structuring tools 22 are coupled to the unit 22 and are thus arranged so that they can be exchanged.

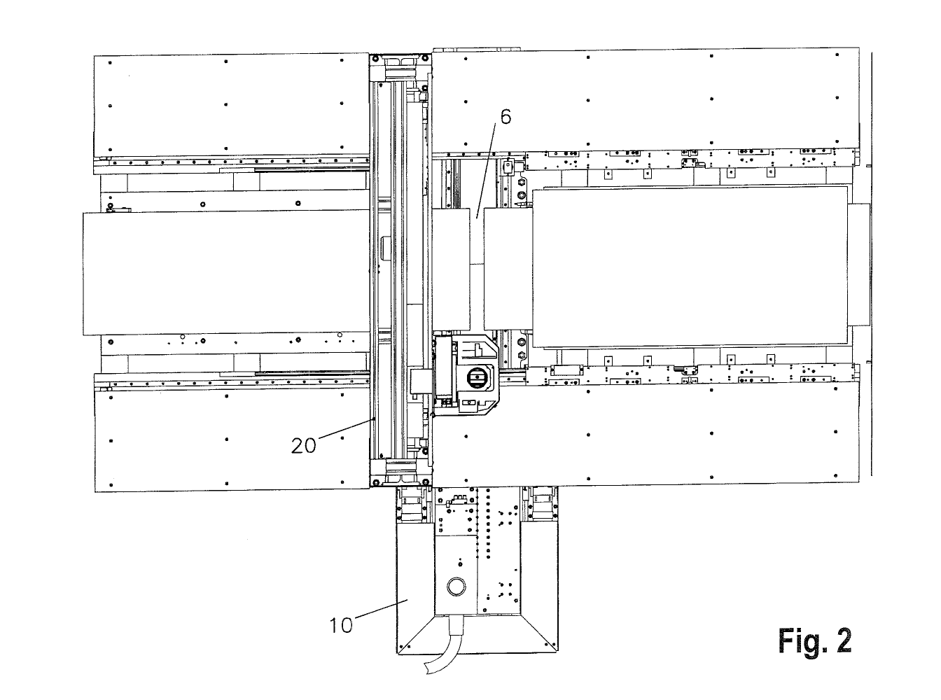

In the plan view in FIG. 2 it can be seen that the gap 6 is arranged over the first transverse axis 10 but offset with respect to the second transverse axis 20.

It will be understood that each of the elements described above, or two or more together, may also find a useful application in other types of constructions differing from the type described above.

While the invention has been illustrated and described as embodied in a system for structuring solar modules, it is not intended to be limited to the details shown, since various modifications and structural changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention.

What is claimed as new and desired to be protected by Letters Patent is set forth in the appended claims:

1. A system for structuring solar modules, comprising a transportation system for transporting a solar module in one transport plane in a first axial direction; a first transport axis with a structural tool, wherein said transportation system has an air cushion system.

2. A system as defined in claim 1, wherein said air cushion system is configured so that it is interrupted by a gap in a processing region.

3. A system as defined in claim 2, wherein said air cushion system is configured so that it is interrupted by said gap in said processing region which is a region of said first transverse axis.

4. A system as defined in claim 2, further comprising a pressure-vacuum table for simultaneously generating a vacuum and an excess pressure between the solar module and a plate in said at least one processing region.

5. A system as defined in claim 1, wherein said structuring tool includes a laser system having at least parts which are movable transversely to said first axial direction and arranged on said first transverse axis.

6. A system as defined in claim 5, wherein said structural tool includes a plurality of said laser systems which are arranged on said first transverse axis.

7. A system as defined in claim 5, wherein said laser system is provided on said first transverse axis for guiding laser beams.

8. A system as defined in claim 6, wherein said plurality of lasers are provided on said transverse axis for guiding laser beams.

9. A system as defined in claim 5, wherein said structuring tool has a laser optics provided on said first transverse axis for guiding laser beams.

10. A system as defined in claim 5, wherein said structuring tool has a plurality of laser optics provided on said first transverse axis for guiding laser beams.

11. A system as defined in claim 1, further comprising a second transverse axis.

12. A system as defined in claim 11, further comprising a plurality of structuring tools arranged on said second transverse axis.

13. A system as defined in claim 12, wherein said structuring tools are tools selected from the group consisting of tools for mechanical structuring, tools for edge deletion, and both.

14. A system as defined in claim 11, wherein one of said transverse axes is arranged above and another of said transverse axis is arranged below said transport plane.

15. A system as defined in claim 11, further comprising a calibration system for calibrating lines to be structured and arranged on one of said first and second transverse axes.

16. A system as defined in claim 11, wherein one of said first and second transverse axes has a suction device.

17. A system as defined in claim 11, further comprising a distance measuring system provided on an axis selected from the group consisting of said first transverse axis, said second transverse axis, and both.

18. A system as defined in claim 15, further comprising linear motors for driving elements selected from the group consisting of said structural tools and said calibration system and provided on an axis selected from the group consisting of said first transverse axis, said second transverse axis, and both.

19. A system as defined in claim 1, further comprising retaining means for fixing the solar module and provided on at least one edge region of the solar module.

20. A system as defined in claim 19, further comprising linear motors for driving said retaining means in said first axial direction.

21. A system as defined in claim 1, wherein said transportation system has alignment means for aligning the solar module.
